(19) United States
(12) Patent Application Publication
(10) Pub. No.: US 2017/0194401 A1
(43) Pub. Date: Jul. 6, 2017

(54) THIN FILM TRANSISTOR FOR DISPLAY DEVICE AND ORGANIC LIGHT EMITTING DIODE DISPLAY DEVICE INCLUDING THE SAME

(71) Applicant: SAMSUNG DISPLAY CO., LTD., YONGIN-SI (KR)

(72) Inventors: SEONG MIN CHO, SEONGNAM-SI (KR); SUK HOON KU, SEOUL (KR)

(21) Appl. No.: 15/209,152

(22) Filed: Jul. 13, 2016

(30) Foreign Application Priority Data
Dec. 31, 2015 (KR) 10-2015-0191445

(51) Int. Cl. H01L 27/32; H01L 29/423; H01L 29/49; H01L 29/786; H01L 29/51

(52) U.S. Cl. CPC H01L 27/3248; H01L 29/78675; H01L 29/513; H01L 29/4908; H01L 29/517; H01L 29/42364; H01L 29/78618; H01L 27/3262; H01L 27/1218

(57) ABSTRACT

The described technology relates generally to a thin film transistor for a display device and an organic light emitting diode display device including the same. An exemplary embodiment provides a thin film transistor for a display device, including: a substrate; a semiconductor that is disposed on the substrate and includes a channel, and a source region and a drain region disposed at opposite sides of the channel; a gate insulating layer that includes a first gate insulating layer disposed on the substrate and the semiconductor, and a second gate insulating layer disposed on the first gate insulating layer and overlapping the channel; a gate electrode disposed on the second gate insulating layer; an interlayer insulating layer disposed directly on the first gate insulating layer and the gate electrode; and a source electrode and a drain electrode that are disposed on the interlayer insulating layer and are connected to the semiconductor, wherein a thickness of a portion of the gate insulating layer overlapped with the gate electrode may be larger than that of a portion of the gate insulating layer overlapped with the source region and that of a portion of the gate insulating layer overlapped with the drain region.

### CROSS-REFERENCE TO RELATED APPLICATIONS

This application claims priority to and the benefit of Korean Patent Application No. 10-2015-0191445 filed in the Korean Intellectual Property Office on Dec. 31, 2015, the entire contents of which are incorporated by reference herein.

### TECHNICAL FIELD

The described technology relates generally to a thin film transistor for a display device, and an organic light emitting diode display device including the same.

### DISCUSSION OF RELATED ART

An organic light emitting diode (OLED) includes two electrodes and an organic emission layer situated between these two electrodes, in which electrons injected from one electrode and holes injected from another electrode are combined in the organic emission layer to generate excitons, and the generated excitons release energy to emit light.

An organic light emitting diode display device includes a plurality of pixels. Each pixel includes an organic light emitting diode which is a self-emissive device, a plurality of thin film transistors for driving the organic light emitting diode, and at least one capacitor. The plurality of thin film transistors generally include switching thin film transistors and driving thin film transistors.

A thin film transistor includes a gate electrode, a semiconductor, a source electrode, and a drain electrode, and may be classified into a top gate type of thin film transistor and a bottom gate type of thin film transistor depending on the position of the gate electrode. For the bottom gate type of thin film transistor, a gate insulating layer is disposed on the semiconductor, the gate electrode is disposed on the gate insulating layer, and the source electrode and the drain electrode are disposed on the gate electrode.

If the gate insulating layer is thin, a distance between the gate electrode and the semiconductor becomes small, and the characteristic of the semiconductor may deteriorate when the device is exposed to high temperature and high voltage. In addition, if the gate insulating layer is thick, impurities may not be easily injected into the semiconductor.

### SUMMARY

The described technology is to provide a thin film transistor for a display device and an organic light emitting diode display device including the same that may provide better reliability of a thin film transistor.

In addition, the present invention is to provide a thin film transistor for a display device and an organic light emitting diode display device including the same that impurities may easily be injected into a semiconductor.

An exemplary embodiment of the present invention provides a thin film transistor for a display device, including: a substrate; a semiconductor that is disposed on the substrate and includes a channel, and a source region and a drain region disposed at opposite sides of the channel; a gate insulating layer that includes a first gate insulating layer disposed on the substrate and the semiconductor, and a second gate insulating layer disposed on the first gate insulating layer and overlapping the channel; a gate electrode disposed on the second gate insulating layer; an interlayer insulating layer disposed directly on the first gate insulating layer and the gate electrode; and a source electrode and a drain electrode that are disposed on the interlayer insulating layer and are connected to the semiconductor, wherein a thickness of a portion of the gate insulating layer overlapped with the gate electrode may be larger than that of a portion of the gate insulating layer overlapped with the source region and that of a portion of the gate insulating layer overlapped with the drain region.

The thickness of the second gate insulating layer may be larger than a thickness of the first gate insulating layer.

The portion of the gate insulating layer overlapped with the gate electrode may include the first gate insulating layer and the second gate insulating layer, and the portion of the gate insulating layer overlapped with the source region and the portion of the gate insulating layer overlapped with the drain region may include the first gate insulating layer and may not include the second gate insulating layer.

The second gate insulating layer and the gate electrode may have substantially the same plan shape.

Each of two opposite side edges of the second gate insulating layer may overlap a border between the channel and the source region, and a border between the channel and the drain region respectively.

The thin film transistor for the display device may further include a first contact hole and a second contact hole both formed in the first gate insulating layer and the interlayer insulating layer to expose at least some of the source region and at least some of the drain region respectively, wherein the source electrode may be connected to the source region through the first contact hole, and the drain electrode may be connected to the drain region through the second contact hole.

The semiconductor may include a first doping region disposed between the channel and the source region, and a second doping region disposed between the channel and the drain region.

Impurities included in the source region and the drain region may be different from impurities included in the first doping region and the second doping region.

The source region and the drain region may include P-type impurities, and the first doping region and the second doing region may include N-type impurities.

The first doping region and the second doping region may overlap the gate electrode and the second gate insulating layer.

An etching rate of the first gate insulating layer may be different from an etching rate of the second gate insulating layer.

The first gate insulating layer may be made of hafnium oxide (HfO₂), and the second gate insulating layer may be made of silicon oxide (SiOx).

The first gate insulating layer may be made of silicon oxide (SiOx), and the second gate insulating layer may be made of hafnium oxide (HfO₂).

The first gate insulating layer may be made of silicon oxide (SiOx), and the second gate insulating layer may be made of silicon nitride (SiNx).

The semiconductor may be made of a polycrystalline silicon material.

An exemplary embodiment of the present invention provides an organic light emitting diode display device, including: a substrate; a driving semiconductor that is disposed on the substrate and includes a channel, and a source region and a drain region disposed at opposite sides of the channel; a gate insulating layer that includes a first gate insulating layer disposed on the substrate and the driving semiconductor, and a second gate insulating layer disposed on the first gate insulating layer and overlapping the channel; a driving gate electrode disposed on the second gate insulating layer; an interlayer insulating layer disposed directly on the first gate insulating layer and the driving gate electrode; a driving source electrode and a driving drain electrode that are disposed on the interlayer insulating layer and are connected to the driving semiconductor; a pixel electrode connected to the driving drain electrode; an organic emission layer disposed on the pixel electrode; and a common electrode disposed on the organic emission layer, wherein a thickness of a portion of the gate insulating layer overlapped with the driving gate electrode may be larger than that of a portion of the gate insulating layer overlapped with the source region and that of a portion of the gate insulating layer overlapped with the drain region.

A thickness of the second gate insulating layer may be larger than a thickness of the first gate insulating layer.

The second gate insulating layer and the driving gate electrode may have substantially the same plan shape.

The driving semiconductor may further include a first doping region interposed between the channel and the source region, and a second doping region interposed between the channel and the drain region.

An etching rate of the first gate insulating layer is different from an etching rate of the second gate insulating.

An exemplary embodiment of the present invention provides a thin film transistor for a display device, including: a substrate; a buffer layer disposed on the substrate; a semiconductor disposed on the buffer layer, the semiconductor including a channel, a source region and a drain region with the source region and the drain region disposed at opposite sides of the channel; a first gate insulating layer disposed on the buffer layer and the semiconductor; a second gate insulating layer disposed on the first gate insulating layer and overlapping the channel but not or minimally overlapping the source region and the drain region; a gate electrode disposed on the second gate insulating layer and having a plan shape substantially the same as that of the second gate insulating layer; an interlayer insulating layer disposed directly on the first gate insulating layer and the gate electrode; and a source electrode and a drain electrode that are disposed on the interlayer insulating layer and are connected to the semiconductor.

A thickness of the second gate insulating layer may be larger than a thickness of the first gate insulating layer.

The semiconductor may include a first doping region disposed between the channel and the source region, and a second doping region disposed between the channel and the drain region.

Impurities included in the source region and the drain region may be different from impurities included in the first doping region and the second doping region.

The thin film transistor for the display device and the organic light emitting diode display device including the same according to the exemplary embodiments of the present invention as described above have the following better features and properties.

According to an exemplary embodiment of the present invention, the thin film transistor for the display device and the organic light emitting diode display device including the same may provide better reliability of thin film transistor by forming a portion of the gate insulating layer overlapped with the gate electrode to be relatively thick.

In addition, the impurities may be easily injected into the semiconductor by forming a portion of the gate insulating layer overlapped with the source region and the drain region of the semiconductor to be relatively thin.

### BRIEF DESCRIPTION OF THE DRAWINGS

FIG. 1 illustrates a cross-sectional view of a thin film transistor for a display device according to an exemplary embodiment of the present invention.

FIG. 2 illustrates a cross-sectional view of a thin film transistor for a display device according to an exemplary embodiment of the present invention.

FIGS. 3 to 5 illustrate a partial process cross-sectional view of a manufacturing process of a thin film transistor for a display device according to an exemplary embodiment of the present invention, respectively.

FIGS. 6 to 8 illustrate a partial process cross-sectional view of a manufacturing process of a thin film transistor for a display device according to a reference example, respectively.

FIG. 9 illustrates an equivalent circuit diagram of one pixel of an organic light emitting diode display device according to an exemplary embodiment of the present invention.

FIG. 10 illustrates a layout view of one pixel of an organic light emitting diode display device according to an exemplary embodiment of the present invention.

FIG. 11 illustrates a cross-sectional view taken along line XI-XI of FIG. 10 according to an exemplary embodiment of the present invention.

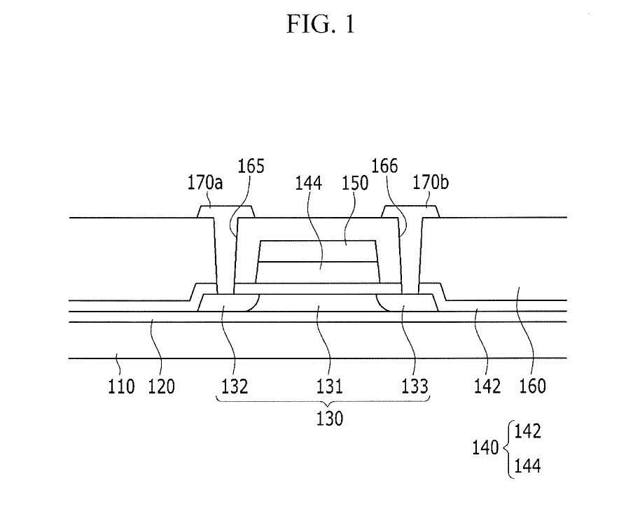

Since the drawings in FIGS. 1-11 are intended for illustrative purposes, the elements in the drawings are not necessarily drawn to scale. For example, some of the elements may be enlarged or exaggerated for clarity purpose.

### DETAILED DESCRIPTION OF THE EMBODIMENTS

The present invention will be described more fully hereinafter with reference to the accompanying drawings, in which exemplary embodiments of the present invention are shown. As those skilled in the art would realize, the described embodiments may be modified in various different ways, all without departing from the spirit or scope of the present invention.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

It will be understood that, although the terms “first”, “second”, “third”, “fourth” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present inventive concept. As used herein, the singular forms “a”, “an” and “the” are intended to include the plural forms as well, unless the context clearly indicates otherwise.

A thin film transistor for a display device according to an exemplary embodiment of the present invention will now be described with reference to FIG. 1.

FIG. 1 illustrates a cross-sectional view of a thin film transistor for a display device according to an exemplary embodiment of the present invention.

As shown in FIG. 1, the thin film transistor for the display device according to an exemplary embodiment of the present invention includes a substrate 110, a semiconductor 130 disposed on the substrate 110, a gate insulating layer 140 disposed on the semiconductor 130, a gate electrode 150 disposed on the gate insulating layer 140, an interlayer insulating layer 160 disposed on the gate electrode 150, and a source electrode 170a and a drain electrode 170b disposed on the interlayer insulating layer 160.

The substrate 110 may be made of an insulating material such as, for example, glass, quartz, ceramic, plastic, or the like.

A buffer layer 120 may further be disposed on the substrate 110, and the semiconductor 130 may be disposed on the buffer layer 120. The buffer layer 120 may be made of an inorganic insulating material such as, for example, silicon nitride (SiNx) or silicon oxide (SiOx). The buffer layer 120 may be configured with a single layer or multiple layers.

The semiconductor 130 includes a channel 131 and contact doping regions 132 and 133 which are disposed at opposite sides of the channel 131 and are doped with impurities. The channel 131 is overlapped with the gate electrode 150, and the contact doping regions 132 and 133 include a source region 132 and a drain region 133. The semiconductor 130 may be made of, for example, polycrystalline silicon material.

The gate insulating layer 140 includes a first gate insulating layer 142 and a second gate insulating layer 144

The first gate insulating layer 142 is disposed on the substrate 110 and the semiconductor 130. The second gate insulating layer 144 is disposed on the first gate insulating layer 142. The second gate insulating layer 144 is overlapped with the channel 131 and the gate electrode 150. Each of two opposite side edges of the second gate insulating layer 144 may be overlapped with a border of the channel 131 and the source region 132, and a border of the channel 131 and the drain region 133, respectively. Thus, the second gate insulating layer 144 may not or minimally overlap the source region 132 and the drain region 133. Depending on the process condition used in injecting the impurities to the semiconductor 130, in many cases, some but not significant of the impurities may spread inward into the channel 131 causing some minor overlap between the second gate insulating layer 144 and both the source region 132 and the drain region 133.

A portion of the gate insulating layer 140 overlapped with the gate electrode 150 includes the first gate insulating layer 142 and the second gate insulating layer 144. In this portion of the gate insulating layer 140, the second gate insulating layer 144 is stacked on top of the first gate insulating layer 142. A portion of the gate insulating layer 140 which is not overlapped with the gate electrode 150 includes only the first gate insulating layer 142, but does not include the second gate insulating layer 144. Particularly, a portion of the gate insulating layer 140 overlapped with the source region 132 and drain region 133 includes the first gate insulating layer 142, but does not include the second gate insulating layer 144.

The first gate insulating layer 142 has a uniform thickness as a whole, and the second gate insulating layer 144 has a uniform thickness as a whole. Thus, the entire thickness of the gate insulating layer 140 may be different depending on its position. A thickness of a portion of the gate insulating layer 140 overlapped with the gate electrode 150 is larger than that of a portion of the gate insulating layer 140 overlapped with the source region 132 and that of a portion of the gate insulating layer 140 overlapped with the drain region 133. That is, the thickness of the gate insulating layer 140 varies depending on whether the second gate insulating layer 144 is included in the gate insulating layer 140. When the second gate insulating layer 144 is included in the gate insulating layer 140, the thickness of the gate insulation layer 140 is the combination of the thickness of the first gate insulating layer 142 and the thickness of the second gate insulating layer 144.

An etching rate of the first gate insulating layer 142 is different from an etching rate of the second gate insulating layer 144 due to different materials chosen for these two insulating layers. For example, the first gate insulating layer 142 may be made of hafnium oxide (HfO₂), and the second gate insulating layer 144 may be made of silicon oxide (SiOx). In this case, after the gate insulating layer 142 and the second gate insulating layer 144 are sequentially stacked and the gate electrode 150 is patterned, the second gate insulating layer 144 is patterned by using the gate electrode 150 as a mask. In this case, a photoresist is used for patterning the gate electrode 150, and the second gate insulating layer 144 may be patterned by using the same photoresist left as a mask. The second gate insulating layer 144 may be patterned by a dry etching process. The silicon oxide (SiOx) is etched by the dry etching process, but the hafnium oxide (HfO₂) is not etched by the dry etching process. Thus, the first gate insulating layer 142 is not damaged during the patterning process of the second gate insulating 144. As a result, the first gate insulating layer 142 may have a uniform thickness.

Alternatively, the first gate insulating layer 142 may be made of silicon oxide (SiOx), and the second gate insulating layer 144 may be made of hafnium oxide (HfO₂). In this case, after the first gate insulating layer 142 and the second gate insulating layer 144 are sequentially stacked and the gate electrode 150 is patterned, the second gate insulating layer 144 may be patterned by using the gate electrode 150 or a photoresist disposed on the gate electrode 150 as a mask. The second gate insulating layer may be patterned by a wet etching process using an isopropyl alcohol:hydrofluoric acid (IPA:HF) solution as an etching solution. The hafnium oxide (HfO₂) is etched by the isopropyl alcohol:hydrofluoric acid (IPA:HF) solution, but the silicon oxide (SiOx) is not etched by the isopropyl alcohol:hydrofluoric acid (IPA:HF) solution. Thus, the first gate insulating layer 142 is not damaged during the patterning process of the second gate insulating layer 144. As a result, the first gate insulating layer 142 may have a uniform thickness.

As the first gate insulating layer 142 and the second gate insulating layer 144 are respectively made of the materials with different etching rates as described above, the first gate insulating layer 142 may be formed to have a constant thickness. The materials with different etching rates, the silicon oxide (SiOx) and the hafnium oxide (HfO₂) shown above are only one example, and various materials may be used. For example, the first gate insulating layer 142 may be made of silicon oxide (SiOx), and the second gate insulating layer 144 may be made of silicon nitride (SiNx).

The gate electrode 150 is disposed on the second gate insulating layer 144. Since the second gate insulating layer 144 is patterned by using the gate electrode 150 or the photoresist used for patterning the gate electrode 150 as a mask, the second gate insulating layer 144 and the gate electrode 150 have a shape with substantially the same flat surface. Since a lateral surface of the gate electrode 150 is partially etched during the etching process of the second gate insulating layer 144, although the sizes of the flat surfaces of the gate electrode 150 and the second gate insulating layer 144 may be slightly varied, the shapes of the flat surfaces are substantially the same. A lateral surface of the gate electrode 150 or the second gate insulating layer 144 may have a tapered shape. Thus, the second gate insulating layer 144 and the gate electrode 150 may or may not have the same thickness, but they have substantially the same plan shape and may also have similar sidewall profile. The second gate insulating layer 144 and the gate electrode 150 may have various plan shapes. If the plan shape is rectangular, the second gate insulating layer 144 and the gate electrode 150 may have flat surfaces with substantially the same width and the same length.

The interlayer insulating layer 160 may be made of an inorganic insulating material or an organic insulating material, and may be formed as a single layer or multiple layers. The interlayer insulating layer 160 is disposed directly on the first gate insulating layer 142 and the gate electrode 150.

The first gate insulating layer 142 and the interlayer insulating layer 160 are provided with contact holes 165 and 166 which expose at least some of an upper portion of the semiconductor 130. The contact holes 165 and 166 particularly expose the source region 132 and the drain region 133 of the semiconductor 130 respectively. Since the second gate insulating layer 144 does not cover the source region 132 and the drain region 133 of the semiconductor 130, the contact holes 165 and 166 is not in the second gate insulating layer 144.

The source electrode 170a and the drain electrode 170b are connected to the semiconductor 130 through the contact holes 165 and 166 respectively. The source electrode 170a is connected to the source region 132 of the semiconductor 130, and the drain electrode 170b is connected to the drain region 133 of the semiconductor 130.

The semiconductor 130, the gate insulating layer 140, the gate electrode 150, the interlayer insulating layer 160, the source electrode 170a, and the drain electrode 170b described above together form a thin film transistor TFT.

In an exemplary embodiment of the present invention, the first gate insulating layer 142 and the second gate insulating layer 144 are interposed between the channel 131 of the semiconductor 130 and the gate electrode 150, and only the first gate insulating layer 142 is disposed on the source region 132 and the drain region 133 of the semiconductor 130.

The gate insulating layer 140 disposed between the channel 131 of the semiconductor 130 and the gate electrode 150 is formed to be relatively thick. When the gate insulating layer 140 interposed between the channel 131 of the semiconductor 130 and the gate electrode 150 is thin, the characteristic of the semiconductor 130 may deteriorate in a high temperature and high voltage condition. In an exemplary embodiment of the present invention, the gate insulating layer 140 interposed between the channel 131 of the semiconductor 130 and the gate electrode 150 is formed to be thick, thereby better reliability of the thin film transistor can be obtained.

In one condition, the gate insulating layer 140 disposed on the source region and the drain region of the semiconductor is formed to be relatively thick. Predetermined impurities are doped in the source region 132 and the drain region 133 of the semiconductor 130. A doping process of the semiconductor 130 is perform by injecting impurity ions by using the gate electrode 150, or the photoresist for the patterning of the gate electrode 150, as a mask. Since the doping process of the semiconductor 130 is performed in a state in which the semiconductor 130 is covered by the gate insulating layer 140, as the thickness of the gate insulating layer 140 becomes larger, the impurities are more difficult to be injected and more energy is required. When the impurities are injected with more energy, the area of the semiconductor 130 into which the impurities are injected becomes wider, the channel length of the semiconductor may then be shortened. In an exemplary embodiment of the present invention, the gate insulating layer 140 disposed on the source region 132 and the drain region 133 of the semiconductor 130 is formed to be thin, thus the doping process may be easily performed and a long channel 131 of the semiconductor 130 may be ensured.

According to an exemplary embodiment of the present invention, better reliability of the thin film transistor may be obtained and the doping process of the semiconductor 130 may be easily performed by varying the thickness of the gate insulating layer 140 depending on the position of the gate insulating layer 140. The first gate insulating layer 142 is preferably thinly formed to facilitate the doping process of the semiconductor 130, and the second gate insulating layer 144 is preferably thickly formed to obtain better reliability of the thin film transistor. Thus, the second gate insulating layer 144 may be formed to be thicker than the first gate insulating layer 142.

When the gate insulating layer 140 is formed as a single layer or as multiple layers in which materials with similar etching rates are stacked, since the first gate insulating layer 142 is damaged during the patterning process of the second gate insulating layer 144 due to insufficient etch rate difference between these two layers, the gate insulating layer 140 may not have a uniform thickness. In an exemplary embodiment of the present invention, the first gate insulating layer 142 and the second gate insulating layer 144 are made of materials with different etching rates under the same etch condition, thus the first gate insulating layer 142 serves as an etch stopper during the patterning process of the second gate insulating layer 144. Thus, the first gate insulating layer is not damaged and may be provided with uniform thickness.

The aforementioned thin film transistor for display devices may be applied to various display devices. For example, it can be applied to thin film transistors disposed on display areas of an organic light emitting diode display device and a liquid crystal display device, and can be applied to thin film transistors of drivers of the above devices. The display area of the organic light emitting diode display device may be provided with the driving thin film transistor, the switching thin film transistor, etc. According to an exemplary embodiment of the present invention, the thin film transistors for the display device may be applied to at least one of the driving thin film transistor and the switching thin film transistor.

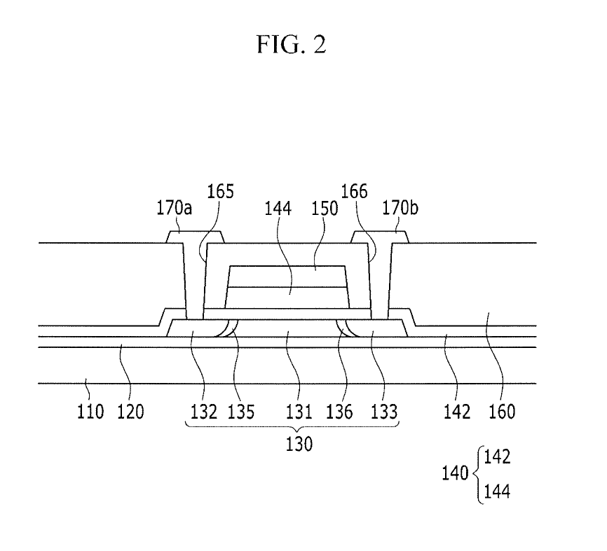

A thin film transistor for the display device according to an exemplary embodiment of the present invention will now be described with reference to FIG. 2.

The thin film transistor for the display device according to an exemplary embodiment of the present invention illustrated in FIG. 2 has substantially the same configuration as the thin film transistor for the display device illustrated in FIG. 1, so a description thereof will be omitted. The current exemplary embodiment differs from the aforementioned exemplary embodiment in that the semiconductor further includes other doping regions in addition to the source region and the drain region, and this will be described in detail below.

FIG. 2 illustrates a cross-sectional view of the thin film transistor for the display device according to an exemplary embodiment of the present invention.

As shown in FIG. 2, the thin film transistor for display device according to an exemplary embodiment of the present invention includes the substrate 110, the semiconductor 130 disposed on the substrate 110, the gate insulating layer 140 disposed on the semiconductor 130, the gate electrode 150 disposed on the gate insulating layer 140, the interlayer insulating layer 160 disposed on the gate electrode 150, and the source electrode 170a and the drain electrode 170b disposed on the interlayer insulating layer 160.

The semiconductor 130 includes the channel 131, and contact doping regions 132 and 133 which are disposed at opposite sides of the channel 131 and are doped with impurities. The contact doping regions 132 and 133 consist of the source region 132 and the drain region 133. The semiconductor 130 may further include a first doping region 135 interposed between the channel 131 and the source region 132, and a second doping region 136 interposed between the channel 131 and the drain region 133. The channel 131, the first doping region 135, and the second doping region 136 are overlapped with the gate electrode 150.

The first doping region 135, the second doping region 136, the source region 132, and the drain region 133, each of them includes a predetermined quantity and/or type of impurities, respectively. The impurities included in the source region 132 and the drain region 133 may be different from the impurities included in the first doping region 135 and the second doping region 136. For example, the source region 132 and the drain region 133 may include P-type impurities such as boron, and the first doping region 135 and the second doping region 136 may include N-type impurities such as phosphorus. On the other hand, the source region 132 and the drain region 133 may include N-type impurities, and the first doping region 135 and the second doping region 136 may include P-type impurities. As the display device becomes large and has high resolution, the size of the thin film transistor becomes small and the length of the channel is shortened. Accordingly, a threshold voltage Vth of the thin film transistor may become small, thus a leakage current may occur. Since the thin film transistor according to an exemplary embodiment of the present invention further includes the first doping region 135 and the second doping region 136 including different impurities from the source region 132 and the drain region 133, it is possible to prevent a threshold voltage from becoming small and a leakage current from occurring.

The gate insulating layer 140 includes the first gate insulating layer 142 and the second gate insulating layer 144. The first gate insulating layer 142 is disposed on the substrate 110 and the semiconductor 130. The second gate insulating layer 144 is disposed on the gate insulating layer 142. The second gate insulating layer 144 overlaps with the channel 131, the first doping region 135 and the second doping region 136, and overlaps with the gate electrode 150. Each of the two opposite side edges of the second gate insulating layer 144 may overlap a border between the first doping region 135 and the source region 132, and a border between the second doping region 136 and the drain region 133, respectively.

A portion of the gate insulating layer 140 overlapped with the gate electrode 150 may include the first gate insulating layer 142 and the second gate insulating layer 144. A portion of the gate insulating layer 140 not overlapped with the gate electrode 150 includes only the first gate insulating layer 142, and does not include the second gate insulating layer 144. Particularly, the portion of the gate insulating layer 140 overlapped with the source region 132 and the drain region 133 includes the first gate insulating layer 142, and does not include the second gate insulating layer 144. Thus, an entire thickness of the gate insulating layer 140 varies depending on its position. The thickness of the portion of the gate insulating layer 140 overlapped with the gate electrode 150 is larger than that of the portion of the gate insulating layer 140 overlapped with the source region 132 and that of the portion of the gate insulating layer 140 overlapped with the drain region 133.

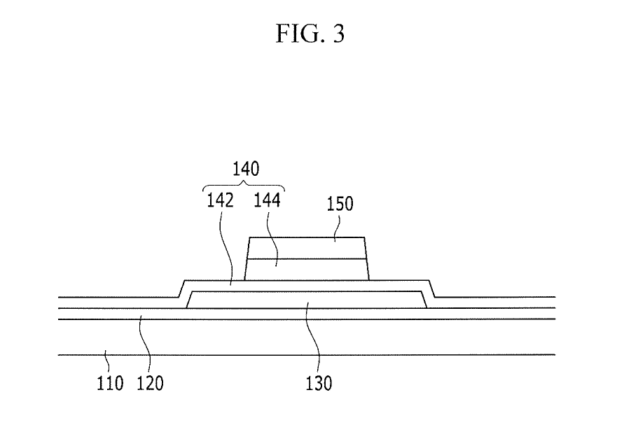

A semiconductor doping process of the thin film transistor for the display device according to an exemplary embodiment of the present invention will now be described with reference to FIGS. 3 to 5.

FIGS. 3 to 5 illustrate a partial process cross-sectional view of a manufacturing process of the thin film transistor for the display device according to an exemplary embodiment of the present invention, respectively.

As shown in FIG. 3, the buffer layer 120 is formed on the substrate 110, and the semiconductor 130 is formed on the buffer layer 120 and is patterned. In this case, the semiconductor 130 is an intrinsic semiconductor in which impurities are not doped. The first gate insulating layer 142 and the second gate insulating layer 144 are sequentially stacked on the semiconductor 130. The gate electrode 150 is formed and patterned on the second gate insulating layer 144. The second gate insulating layer 144 is patterned by using the gate electrode 150 as a mask. In this case, in a state in which a photoresist used for the patterning of the gate electrode 150 is not removed, the second gate insulating layer 144 may be patterned by using the unremoved photoresist as a mask.

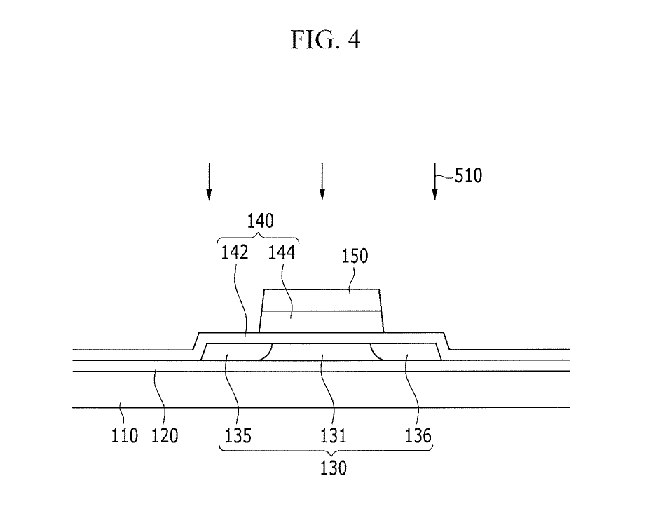

As shown in FIG. 4, a doping process for injecting N-type impurity ions 510 is performed by using the gate electrode 150 as a mask. In this case, in a state in which a photoresist is used for the patterning of the gate electrode 150, the doping process may be performed by using the photoresist as a mask. The semiconductor 130 includes the channel 131, and the first doping region 135 and the second doping region 136 disposed at the opposite sides of the channel 131. By injecting N-type impurity ions 510 with relatively strong energy, the first doping region 135 and the second doping region 136 may be spread to the regions where they are overlapped with the gate electrode 150. When the N-type impurity ions 510 are injected into the semiconductor 130, they are spread to a longer distance on the surface of the semiconductor 130, and the distance that the N-type impurity ions 510 spread becomes shorter when the N-type impurity ions 510 penetrates deeper and farther away from the surface of the semiconductor 130. Thus, in the border between the channel 131 and the first doping region 135, the penetration of N-type impurity ions 510 into the first doping region 135 becomes deeper as the injection position being farther away from the center of the channel 131. Moreover, in the border between the channel 131 and the second doping region 136, the penetration of N-type impurity ions 510 into the second doping region 136 becomes deeper as the injection position being farther away from the center of the channel 131.

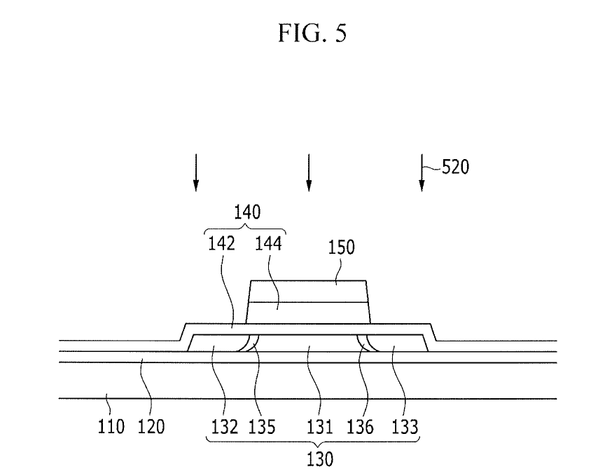

As shown in FIG. 5, a doping process for injecting P-type impurity ions 520 is performed by using the gate electrode 150 or the photoresist used for the patterning of the gate electrode 150 as a mask. The semiconductor 130 further includes the source region 132 contacting the first doping region 135 and the drain region 133 contacting the second doping region 136. The first doping region 135 is interposed between the channel 131 and the source region 132, and the second doping region 136 is interposed between the channel 131 and the drain region 133. The source region 132 and the drain region 133 do not substantially overlap the gate electrode 150 by injecting the P-type impurity ions 520 while using relatively weak energy. When the P-type impurity ions 520 are injected into the semiconductor, they are spread to a longer distance on the surface of the semiconductor 130, and the spreading distance of the P-type impurity ions 520 becomes shorter when the P-type impurity ions 520 penetrates deeper and farther away from the surface of the semiconductor 130. Thus, in the border between the first doping region 135 and the source region 136, the penetration of P-type impurity ions 520 into the source region 132 becomes deeper as the injection position being farther away from the center of the channel 131. Furthermore, in the border between the second doping region 136 and the drain region 133, the penetration of P-type impurity ions 520 into the drain region 133 becomes deeper as the injection position being farther away from the center of the channel 131.

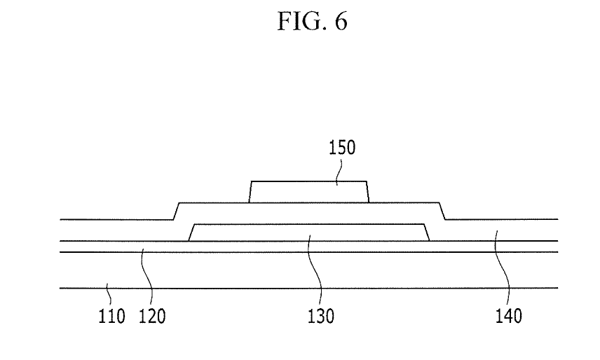

A semiconductor doping process of a thin film transistor for a display device according to a reference example will be described while comparing with the exemplary embodiment of the present invention, with reference to FIGS. 6 to 8.

FIGS. 6 to 8 illustrate a partial process cross-sectional view of a manufacturing process of a thin film transistor for a display device according to a reference example, respectively.

As shown in FIG. 6, the buffer layer 120 is disposed on the substrate 110, and the semiconductor 130 is disposed on the buffer layer 20 and is patterned. The gate insulating layer 140 made of a single material is disposed on the semiconductor 130. In this case, for comparison, in the exemplary embodiment of the present invention, the gate insulating layer 140 substantially has a thickness of about the sum of the thicknesses of the first gate insulating layer 142 and the second gate insulating layer 144. The gate electrode 150 is disposed on the gate insulating layer 140 and is patterned.

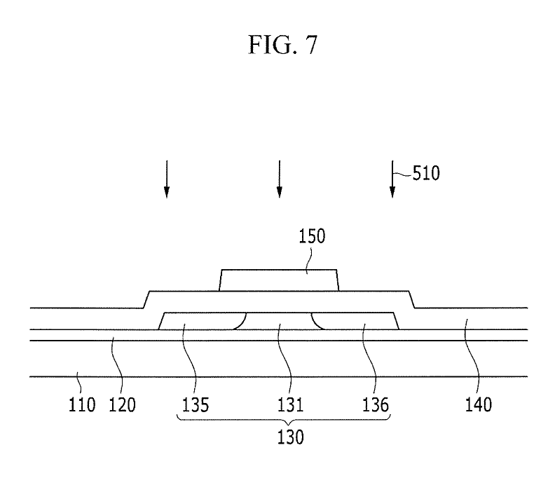

As shown in FIG. 7, a doping process for injecting N-type impurity ions 510 is performed by using the gate electrode 150 as a mask. Considering that the gate insulating layer 140 is generally thick, the N-type impurity ions 510 is injected with more energy than that used for the injecting process of the N-type impurity ions 510 in the exemplary embodiment shown in FIG. 4. Thus, the areas of the first doping region 135 and the second doping region 136 become larger than those of the exemplary embodiment shown in FIG. 4.

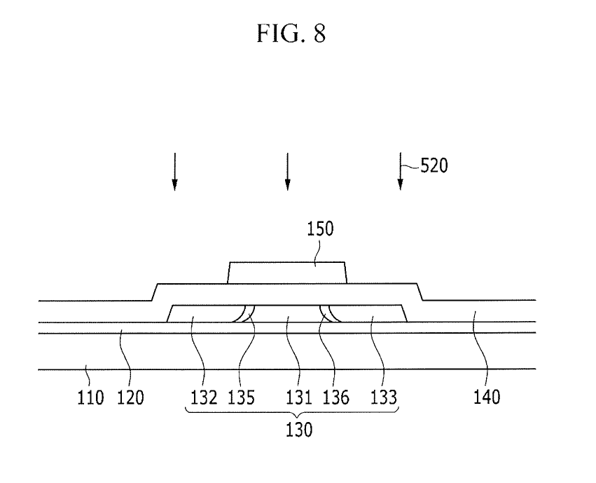

As shown in FIG. 8, a doping process for injecting P-type impurity ions 520 is performed by using the gate electrode 150 as a mask. Considering that the gate insulating layer 140 is generally thick, the P-type impurity ions 520 is injected with more energy than that used for the injecting process of the P-type impurity ions 520 in the exemplary embodiment shown in FIG. 5. Thus, the areas of the source region 132 and the drain region 133 become larger than those of the exemplary embodiment shown in FIG. 5.

When the gate insulating layer 140 is formed as a thick single layer, many impurities are lost due to the thick layer of the gate insulating layer 140 during the impurity injecting process, so the impurities may not be easily injected through the gate insulating layer 140 into the semiconductor 130. Thus, for injecting the impurities, stronger energy is required, or longer processing time is required. Further, as shown in FIG. 8, a length of the channel becomes shorter. On the other hand, when the gate insulating layer 140 is formed as a thin single layer, the reliability of the thin film transistor deteriorates.

In the thin film transistor for the display device according to an exemplary embodiment of the present invention, the portion of the gate insulating layer overlapped with the gate electrode is formed to be thick and the portion of the gate insulating layer overlapped with the source region and the drain region into which the impurities are injected is formed to be thin, thereby obtaining better reliability of the thin film transistor and easily injecting the impurities. Moreover, since the impurities are injected with less energy, it is possible to effectively ensure the channel length and to reduce the processing time. Further, the gate insulating layer includes the first gate insulating layer and the second gate insulating layer which are made of materials with different etching rates, and the thickness of the gate insulating layer is adjusted depending on whether to form the second gate insulating layer on top of the first gate insulating layer, thereby allowing forming uniform thickness of the first gate insulating layer.

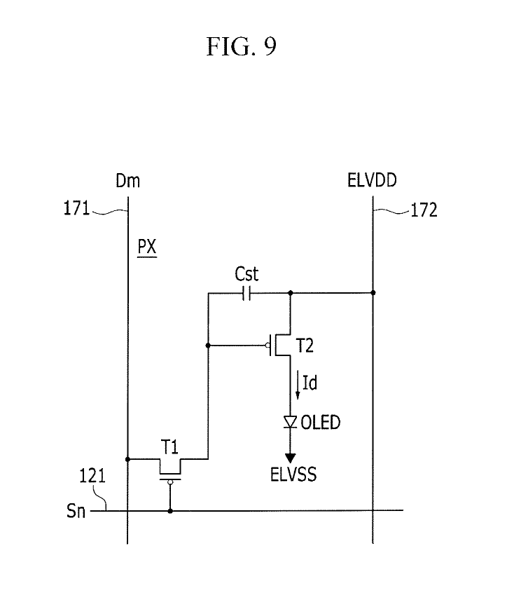

An organic light emitting diode display device according to an exemplary embodiment of the present invention will now be described with reference to FIGS. 9 to 11. In FIGS. 9 to 11, a thin film transistor of the light emitting diode display device according to an exemplary embodiment of the present invention is shown to have the same structure as the thin film transistor shown in FIG. 1, but the present invention is not limited thereto, and may have the structure of the thin film transistor shown in FIG. 2.

FIG. 9 illustrates an equivalent circuit diagram of one pixel of the organic light emitting diode display device according to an exemplary embodiment of the present invention.

As shown in FIG. 9, one pixel of the organic light emitting diode display device according to an exemplary embodiment of the present invention includes a plurality of signal lines 121, 171, and 172, a plurality of transistors T1 and T2 connected to the plurality of signal lines, a storage capacitor Cst, and an organic light emitting diode (OLED).

The transistors T1 and T2 consist of a switching transistor T1 and a driving transistor T2.

The signal lines 121, 171, and 172 include a plurality of gate lines 121 transmitting a gate signal Sn, a plurality of data lines 171 crossing the gate lines and transmitting a data signal Dm, and a plurality of driving voltage lines 172 transmitting a driving voltage ELVDD and being substantially parallel to the data lines 171.

The switching transistor T1 is provided with a control terminal, an input terminal, and an output terminal. The control terminal of the switching transistor T1 is connected to the gate line 121, the input terminal is connected to the data line 171, and the output terminal is connected to the driving transistor T2. The switching transistor T1 transmits a data signal Dm applied to the data line 171 to the driving transistor T2 in response to a gate signal Sn applied to the gate line 121.

The driving transistor T2 is also provided with a control terminal, an input terminal, and an output terminal. The control terminal of the driving transistor (T2) is connected to the switching transistor T1, the input terminal is connected to the driving voltage line 172, and the output terminal is connected to the organic light emitting diode OLED. The driving transistor T2 outputs a driving current Id, and the amount of the driving current Id varies depending on the voltage applied between the control terminal and the output terminal.

The storage capacitor Cst is connected between the control terminal and the input terminal of the driving transistor T2. The storage capacitor Cst is charged by the data signal applied to the control terminal of the driving transistor T2, and maintains the data signal even after the switching terminal T1 is turned off.

The organic light emitting diode (OLED) is provided with an anode connected to the driving transistor T2 and a cathode connected to a common voltage ELVSS. The OLED displays an image by emitting light, the intensity of which varies depending on the driving current Id of the driving transistor T2.

The switching transistor T1 and the driving transistor T2 may be n-channel field effect transistors (FETs) or p-channel field effect transistors. A connection relationship between the transistors T1 and T2, the storage capacitor Cst, and the OLED may be variously changed.

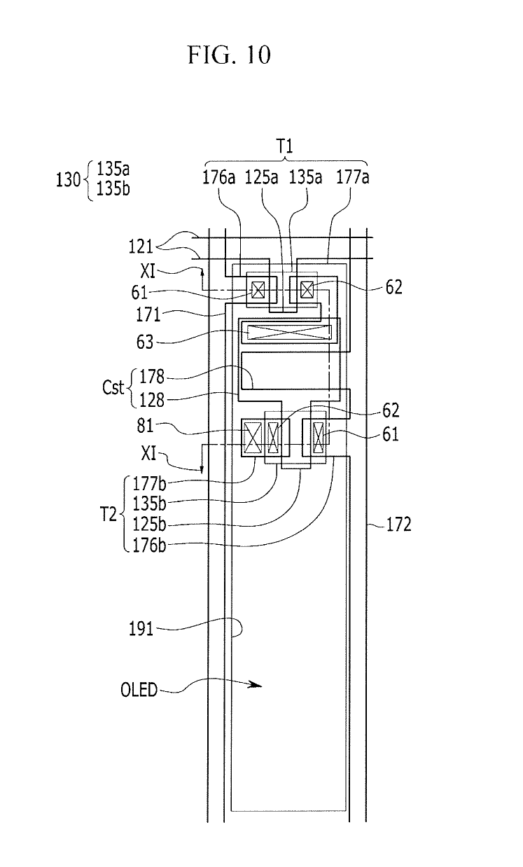

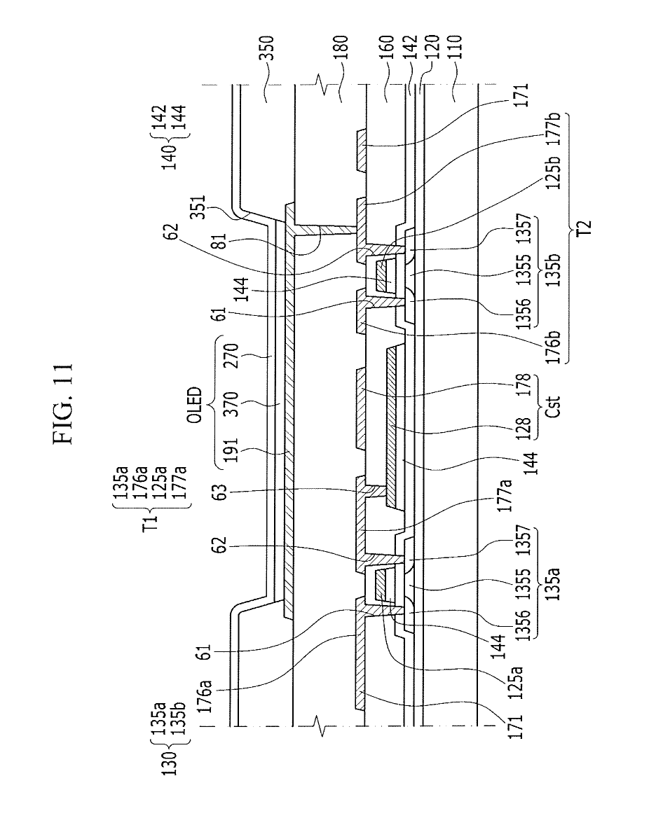

Now, a detailed structure of the pixel of the organic light emitting diode display device according to an exemplary embodiment of the present invention shown in FIG. 9 will be described in detail with reference to FIG. 10 and FIG. 11 as well as FIG. 9.

FIG. 10 illustrates a layout view of one pixel of the organic light emitting diode display device according to an exemplary embodiment of the present invention, and FIG. 11 illustrates a cross-sectional view taken along line XI-XI of FIG. 10.

As shown in FIGS. 10 and 11, in the organic light emitting diode display device according to an exemplary embodiment of the present invention, a buffer layer 120 is disposed on a substrate 110. The substrate 110 may be formed as an insulating substrate which is made of, for example, glass, quartz, ceramic, plastic, or the like, and the buffer layer 120 may be made of, for example, silicon nitride (SiNx) or silicon oxide (SiOx). The buffer layer 120 may be formed as a single layer or multiple layers. The buffer layer 120 serves to flatten a surface while preventing undesirable materials such as impurities or moisture from being permeated.

A semiconductor 130 is disposed on the buffer layer 120. The semiconductor 130 includes a switching semiconductor 135a and a driving semiconductor 135b disposed at positions which are spaced apart from each other. The semiconductor 130 may be made of, for example, a polycrystalline material or an oxide semiconductor material. In the case that the semiconductor 130 is made of the oxide semiconductor, an additional protecting layer may be added to protect the oxide semiconductor, which is vulnerable to an external environment such as a high temperature and the like.

Each of the switching semiconductor 135a and the driving semiconductor 135b includes a channel 1355, and a source region 1356 and a drain region 1357 disposed at opposite sides of the channel 1355. The source region 1356 and the drain region 1357 of the switching semiconductor 135a and the driving semiconductor 135b are contact doping regions 1356 and 1357 that include impurities such as P-type impurities or N-type impurities.

A gate insulating layer 140 is disposed on the switching semiconductor 135a and the driving semiconductor 135b. The gate insulating layer 140 includes a first gate insulating layer 142 and a second gate insulating layer 144. The first gate insulating layer 142 is disposed on the substrate 110, the switching semiconductor 135a, and the driving semiconductor 135b. The second gate insulating layer 144 is disposed on the first gate insulating layer 142. The second gate insulating layer 144 overlaps the channel. Each of the two opposite side edges of the second gate insulating layer 144 may overlap a border between the channel 1355 and the source region 1356, and a border between the channel 1355 and the drain region 1357, respectively.

A gate line 121, a switching gate electrode 125a, a driving gate electrode 125b, and a first storage capacitor plate 128 are formed on the gate insulating layer 140. The gate line 121, the switching gate electrode 125a, the driving gate electrode 125b, and the first storage capacitor plate 128 are disposed directly on the second gate insulating layer 144. The gate line 121 extends in a horizontal direction to transmit the gate signal Sn. The switching gate electrode 125a protrudes from the gate line 121 above the switching semiconductor 135a. The driving gate electrode 125b protrudes from the first storage capacitor plate 128 above the driving semiconductor 135b. The switching gate electrode 125a and the driving gate electrode 125b each overlaps the channel.

A portion of the gate insulating layer 140 overlapped with the gate line 121, the switching gate electrode 125a, the driving gate electrode 125b, and the first storage capacitor plate 128 includes the first gate insulating layer 142 and the second insulating layer 144. A portion of the gate insulating layer 140 not overlapped with the gate line 121, the switching gate electrode 125a, the driving gate electrode 125b, and the first storage capacitor plate 128 includes only the first gate insulating layer 142, and does not include the second gate insulating layer 144. Particularly, the portion of the gate insulating layer 140 overlapped with the source region 1356 and the drain region 1357 includes the first gate insulating layer 142, and does not include the second gate insulating layer 144.

The first gate insulating layer 142 generally has a uniform thickness, and the second gate insulating layer 144 generally has a uniform thickness. Thus, the entire thickness of the gate insulating layer 140 varies depending on its position. The thickness of the portion of the gate insulating layer 140 overlapped with the gate electrode 150 is larger than that of the portion of the gate insulating layer 140 overlapped with the source region 1356 and that of the portion of the gate insulating layer 140 overlapped with the drain region 1357. That is, the thickness of the gate insulating layer 140 varies depending on whether the gate insulating layer 140 includes the second gate insulating layer 144.

The first gate insulating layer 142 and the second gate insulating layer 144 are made of materials with different etching rates. For example, the gate insulating layer 142 is made of hafnium oxide (HfO₂), and the second gate insulating layer 144 is made of silicon oxide (SiOx). Alternatively, the first gate insulating layer 142 may be made of silicon oxide (SiOx), and the second gate insulating layer 144 may be made of hafnium oxide (HfO₂). As a further alternative, the first gate insulating layer 142 may be made of silicon oxide (SiOx), and the second gate insulating layer 144 may be made of silicon nitride (SiNx).

Since the second gate insulating layer 144 is patterned by using the gate line 121, the switching gate electrode 125a, the driving gate electrode 125b, and the first storage capacitor plate 128, or the photoresist used for the patterning thereof, as a mask, the second gate insulating layer may have the flat surface shape or shapes, such as the plan shape or shapes, substantially the same as those of the gate line 121, the switching gate electrode 125a, the driving gate electrode 125b, and the first storage capacitor plate 128.

An interlayer insulating layer 160 is disposed on the first gate insulating layer 142, the gate line 121, the switching gate electrode 125a, the driving gate electrode 125b, and the first storage capacitor plate 128. The interlayer insulating layer 160 is made of an inorganic insulating material or an organic insulating material. The interlayer insulating layer 160 may be formed as a single layer or multiple layers. The interlayer insulating layer 160 is disposed directly on the first gate insulating layer 142, the gate line 121, the switching gate electrode 125a, the driving gate electrode 125b, and the first storage capacitor plate 128.

Contact holes 61 and 62, which expose at least some of an upper surface of the semiconductor 130, are formed in the first gate insulating layer 142 and the interlayer insulating layer 160. The contact holes 61 and 62 particularly expose the contact doping regions 1356 and 1357 of the semiconductor 130 respectively. Moreover, a storage contact hole 63, which exposes some of the first storage capacitor plate 128, is formed in the interlayer insulating layer 160.

A data line 171, a driving voltage line 172, a switching source electrode 176a, a driving source electrode 176b, a second storage capacitor plate 178, a switching drain electrode 177a, and a driving drain electrode 177b are disposed on the interlayer insulating layer 160.

The data line 171 transmits the data signal Dm, and extends in a direction crossing the gate line 121. The driving voltage line 172 transmits the driving voltage ELVDD, is separated from the data line 171, and extends in a direction parallel to the data line 171.

The switching source electrode 176a protrudes from the data line 171 toward the switching semiconductor, and the driving source electrode 176b protrudes from the driving voltage line 172 toward the driving semiconductor 135b. The switching source electrode 176a and the driving source electrode 176b are respectively connected to the source region 1356 through the contact hole 61.

The switching drain electrode 177a faces the switching source electrode 176a, the driving drain electrode 177b faces the driving source electrode 176b, and the switching drain electrode 177a and the driving drain electrode 177b are respectively connected to the drain region 1357 through the contact hole 62.

The switching drain electrode 177a extends to be electrically connected to the first storage capacitor plate 128 and the driving gate electrode 125b through the storage contact hole 63 formed in the interlayer insulating layer 160.

The second storage capacitor plate 178 protrudes from the driving voltage line 172 to be overlapped with the first storage capacitor plate 128. Thus, the first storage capacitor plate 128 and the second storage capacitor plate 178 form the storage capacitor Cst by using the interlayer insulating layer 160 as a dielectric material.

The switching semiconductor 135a, the gate insulating layer 140, the interlayer insulating layer 160, the switching gate electrode 125a, the switching source electrode 176a, and the switching drain electrode 177a together form the switching transistor T1, and the driving semiconductor 135b, the gate insulating layer 140, the interlayer insulating layer 160, the driving gate electrode 125b, the driving source electrode 176b, and the driving drain electrode 177b together form the driving transistor T2.

A passivation layer 180 is disposed on the data line 171, the driving voltage line 172, the switching source electrode 176a, the driving source electrode 176b, the second storage capacitor plate 178, the switching drain electrode 177a, and the driving drain electrode 177b. The passivation layer 180 is provided with a contact hole 81 which exposes at least some of the drain electrode 177b.

A pixel electrode 191 is disposed on the passivation layer 180, and the pixel electrode 191 may be made of a transparent conductive material such as, for example, indium tin oxide (ITO), indium zinc oxide (IZO), zinc oxide (ZnO), indium oxide (In₂O₃), etc., or a reflective metal such as, for example, lithium (Li), calcium (Ca), lithium fluoride/calcium (LiF/Ca), lithium fluoride/aluminum (LiF/Al), aluminum (Al), silver (Ag), magnesium (Mg), gold (Au), etc. The pixel electrode 191 is electrically connected to the driving drain electrode 177b of the driving transistor T2 via the contact hole 81 to become the anode of the OLED.

A pixel defining layer 350 is formed on the passivation layer 180 and an edge portion of the pixel electrode 191. The pixel defining layer 350 includes a pixel opening 351 that exposes the pixel electrode 191. The pixel defining layer 350 may include, for example, a polyacrylate resin, a polyimide resin, a silica-based inorganic material, etc.

An organic emission layer 370 is formed in the pixel opening 351 of the pixel defining layer 350. The organic emission layer 370 may include at least one of an emission layer, a hole injection layer (HIL), a hole transporting layer (HTL), an electron transporting layer (ETL), and an electron injection layer (EIL). When the organic emission layer 370 includes all of them described above, the hole injection layer is disposed on the pixel electrode 191 which is an anode electrode, and the hole transporting layer, the emission layer, the electron transporting layer, and the electron injection layer may be sequentially stacked on the hole injection layer.

The organic emission layer 370 may include a red organic emission layer for emitting red light, a green organic emission layer for emitting green light, and a blue organic emission layer for emitting blue light. The red organic emission layer, the green organic emission layer, and the blue organic emission layer are respectively formed on red, green, and blue pixels to implement a color image.

Alternatively, in the organic emission layer 370, a color image may be implemented by laminating all of the red, green, and blue organic emission layers on the red pixel, the green pixel, and the blue pixel and then forming red, green, and blue color filters for each pixel. As another example, a color image may be implemented by forming a white organic emission layer emitting white light on all of the red, green, and blue pixels and respectively forming red, green, and blue color filters for each pixel. When the color image is implemented by using the white organic emission layer and the color filter, a deposition mask for depositing the red, green, and blue organic emission layers on each pixel, that is, the red, green, and blue pixels, is not required.

The white organic emission layer described in an exemplary embodiment of the present invention may be formed as a single organic emission layer, and may further include a structure for emitting white light by laminating a plurality of organic emission layers. For example, a structure for emitting white light by combining at least one yellow organic emission layer with at least one blue organic emission layer, a structure for emitting white light by combining at least one cyan organic emission layer with at least one red organic emission layer, and a structure for emitting white light by combining at least one magenta organic emission layer with at least one green organic emission layer may be included.

A common electrode 270 is disposed on the pixel defining layer 350 and the organic emission layer 370. The common electrode 270 may be made of a transparent conductive material such as, for example, indium tin oxide (ITO), indium zinc oxide (IZO), zinc oxide (ZnO), indium oxide (In2O3), etc., or a reflective metal such as, for example, lithium (Li), calcium (Ca), lithium fluoride/calcium (LiF/Ca), lithium fluoride/aluminum (LiF/Al), aluminum (Al), silver (Ag), magnesium (Mg), gold (Au), etc. The common electrode 270 becomes the cathode of the OLED. The pixel electrode 191, the organic emission layer 370, and the common electrode 270 together form the OLED.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the present invention as defined by the appended claims.

What is claimed is:

1. A thin film transistor for a display device, comprising:
a substrate;
a semiconductor that is disposed on the substrate and includes a channel, and a source region and a drain region disposed at opposite sides of the channel;
a gate insulating layer that includes a first gate insulating layer disposed on the substrate and the semiconductor, and a second gate insulating layer disposed on the first gate insulating layer and overlapping the channel;
a gate electrode disposed on the second gate insulating layer;
an interlayer insulating layer disposed directly on the first gate insulating layer and the gate electrode; and
a source electrode and a drain electrode that are disposed on the interlayer insulating layer and are connected to the semiconductor,
wherein a thickness of a portion of the gate insulating layer overlapped with the gate electrode is larger than that of a portion of the gate insulating layer overlapped with the source region and that of a portion of the gate insulating layer overlapped with the drain region.

2. The thin film transistor for the display device of claim 1, wherein
a thickness of the second gate insulating layer is larger than a thickness of the first gate insulating layer.

3. The thin film transistor for the display device of claim 1, wherein
the portion of the gate insulating layer overlapped with the gate electrode includes the first gate insulating layer and the second gate insulating layer, and
the portion of the gate insulating layer overlapped with the source region and the portion of the gate insulating layer overlapped with the drain region include the first gate insulating layer and do not include the second gate insulating layer.

4. The thin film transistor for the display device of claim 1, wherein
the second gate insulating layer and the gate electrode have substantially the same plan shape.

5. The thin film transistor for the display device of claim 1, wherein
each of two opposite side edges of the second gate insulating layer overlaps a border between the channel and the source region and a border between the channel and the drain region respectively.

6. The thin film transistor for the display device of claim 1, further comprising
a first contact hole and a second contact hole both formed in the first gate insulating layer and the interlayer insulating layer to expose at least some of the source region and at least some of the drain region respectively,
wherein the source electrode is connected to the source region through the first contact hole, and the drain electrode is connected to the drain region through the second contact hole.

7. The thin film transistor for the display device of claim 1, wherein
the semiconductor includes:
a first doping region disposed between the channel and the source region; and
a second doping region disposed between the channel and the drain region.

8. The thin film transistor for the display device of claim 7, wherein
impurities included in the source region and the drain region are different from impurities included in the first doping region and the second doping region.

9. The thin film transistor for the display device of claim 7, wherein
the source region and the drain region include P-type impurities, and
the first doping region and the second doing region include N-type impurities.

10. The thin film transistor for the display device of claim 7, wherein
the first doping region and the second doping region overlap the gate electrode and the second gate insulating layer.

11. The thin film transistor for the display device of claim 1, wherein
an etching rate of the first gate insulating layer is different from an etching rate of the second gate insulating layer.

12. The thin film transistor for the display device of claim 11, wherein
the first gate insulating layer is made of hafnium oxide (HfO₂), and the second gate insulating layer is made of silicon oxide (SiOx).

13. The thin film transistor for the display device of claim 11, wherein
the first gate insulating layer is made of silicon oxide (SiOx), and the second gate insulating layer is made of hafnium oxide (HfO₂).

14. The thin film transistor for the display device of claim 11, wherein
the first gate insulating layer is made of silicon oxide (SiOx), and the second gate insulating layer is made of silicon nitride (SiNx).

15. The thin film transistor for the display device of claim 1, wherein
the semiconductor is made of a polycrystalline silicon material.

16. An organic light emitting diode display device, comprising:
a substrate;
a driving semiconductor that is disposed on the substrate and includes a channel, and a source region and a drain region disposed at opposite sides of the channel;
a gate insulating layer that includes a first gate insulating layer disposed on the substrate and the driving semiconductor, and a second gate insulating layer disposed on the first gate insulating layer and overlapping the channel;
a driving gate electrode disposed on the second gate insulating layer;
an interlayer insulating layer disposed directly on the first gate insulating layer and the driving gate electrode;
a driving source electrode and a driving drain electrode that are disposed on the interlayer insulating layer and are connected to the driving semiconductor;
a pixel electrode connected to the driving drain electrode;
an organic emission layer disposed on the pixel electrode; and
a common electrode disposed on the organic emission layer,
wherein a thickness of a portion of the gate insulating layer overlapped with the driving gate electrode is larger than that of a portion of the gate insulating layer overlapped with the source region and that of a portion of the gate insulating layer overlapped with the drain region.

17. The organic light emitting diode display device of claim 16, wherein
a thickness of the second gate insulating layer is larger than a thickness of the first gate insulating layer.

18. The organic light emitting diode display device of claim 16, wherein
the second gate insulating layer and the driving gate electrode have substantially the same plan shape.

19. The organic light emitting diode display device of claim 16, wherein
the driving semiconductor includes:
a first doping region disposed between the channel and the source region; and
a second doping region disposed between the channel and the drain region.

20. The organic light emitting diode display device of claim 16, wherein
an etching rate of the first gate insulating layer is different from an etching rate of the second gate insulating layer.

21. A thin film transistor for a display device, comprising:
a substrate;
a buffer layer disposed on the substrate;
a semiconductor disposed on the buffer layer, the semiconductor including a channel, a source region and a drain region with the source region and the drain region disposed at opposite sides of the channel;
a first gate insulating layer disposed on the buffer layer and the semiconductor;
a second gate insulating layer disposed on the first gate insulating layer and overlapping the channel but not or minimally overlapping the source region and the drain region;
a gate electrode disposed on the second gate insulating layer and having a plan shape substantially the same as that of the second gate insulating layer;
an interlayer insulating layer disposed directly on the first gate insulating layer and the gate electrode; and
a source electrode and a drain electrode that are disposed on the interlayer insulating layer and are connected to the semiconductor.

22. The thin film transistor for the display device of claim 21, wherein
a thickness of the second gate insulating layer is larger than a thickness of the first gate insulating layer.

23. The thin film transistor for the display device of claim 21, wherein
the semiconductor includes:
a first doping region disposed between the channel and the source region; and
a second doping region disposed between the channel and the drain region.

24. The thin film transistor for the display device of claim 23, wherein
impurities included in the source region and the drain region are different from impurities included in the first doping region and the second doping region.
